(19) United States
(12) Patent Application Publication
(10) Pub. No.: US 2009/0085076 A1
(43) Pub. Date: Apr. 2, 2009

(54) Photo Sensor and a Method for Manufacturing Thereof

(75) Inventors: Wei-Chou Lan, Hsinchu (TW); Henry Wang, Hsinchu (TW); Lee-Tyng Chen, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: PRIME VIEW INTERNATIONAL CO., LTD., Hsinchu (TW)

(21) Appl. No.: 12/115,765

(22) Filed: May 6, 2008

(30) Foreign Application Priority Data
Sep. 28, 2007 (TW) 96136417

(51) Int. Cl. H01L 27/146; H01L 31/18

(52) U.S. Cl. 257/292; 438/59; 257/E27.146

(57) ABSTRACT

According to a method of manufacturing photo sensor, a diode can be formed by one lithography step. In addition, the source/drain is arranged on a gate dielectric layer to avoid the conventional plug structure. Moreover, a diode stack is formed on one of the source/drain to simplify the structure of the photo sensor.

### RELATED APPLICATIONS

This application claims priority to Taiwan Application Serial Number 96136417, filed Sep. 28, 2007, which is herein incorporated by reference.

### BACKGROUND

1. Field of Invention

The present invention relates to a method of manufacturing a semiconductor device. More particularly, the present invention relates to a method of manufacturing a photo sensor.

2. Description of Related Art

A “Sensor” detects heat, light or magnetic fields and converts the detected physical parameter into electronic signals. By using the signal generated by the sensor, the user can obtain information therefrom.

According to above, the data can be produced by a photo sensor that generates a current with light. The photo sensor can be divided into two parts, a transistor and a diode. The mechanism of the photo sensor is that the light is directed to the diode to generate a current, and then the current is amplified from tens to hundreds of times to produce a stronger signal. One kind of diode used in the photo sensor is PIN diode. The major difference between the PIN diode and the common diode is an intrinsic layer arranged between a p-doped semiconductor layer and a n-doped conductor layer so that the depletion region between the p-doped and n-doped conductor layers is enlarged. Therefore, it can generate more current after illuminating.

However, in the prior art, the conventional method for fabricating a photo sensor needs to perform at least 7 times of photolithography wherein at least two of which are for forming a PIN diode of the photo sensor. Sometimes, it even needs to be performed 11 times. Besides, since a plug structure is used for the source/drain of the conventional photo sensor, times of performing the photolithography is increased. Accordingly, the conventional process is too complicated which raises the numbers of the mask used due to many times of photolithography steps, and the cost is increased as well.

Therefore, there is a need for developing a simplified method of manufacturing a photo sensor.

### SUMMARY

The present invention is to provide a method of manufacturing a photo sensor to simplify the conventional process.

It is therefore an objective of the present invention to provide a method of manufacturing photo sensor. First, a substrate having a switching element region and an electronic element region is provided. Next, a gate is formed on the switching element region of the substrate. A gate dielectric layer, a semiconductor layer, and an electrical property enhancement layer are formed in sequence to cover the gate and the substrate. After that, the electrical property enhancement layer and the semiconductor layer are patterned to form a channel region on the gate dielectric layer above the gate. Then, a first conductive layer, a plurality of element function layers and a second conductive layer are formed in sequence to cover the gate dielectric layer and the channel region. Next, the second conductive layer and the element function layers are patterned wherein the element function layers patterned form a diode stack on the first conductive layer of the electronic element region, and the second conductive layer patterned forms a photoelectrode on the diode stack. Furthermore, the first conductive layer is patterned to form a source/drain above the opposite sides of the channel region and expose a part of the electrical property enhancement layer. Then, a insulating layer is formed to cover the source/drain, the diode stack and the photoelectrode. The insulating layer is patterned to form an opening in the insulating layer and the opening exposes the photoelectrode. Moreover, a third conductive layer is formed to cover the insulating layer and the photoelectrode. Finally, the third conductive layer is patterned so that the third conductive layer patterned covers a part of the insulating layer above the source/drain and connects to one side of the photoelectrode near the source/drain along the opening.

It is another an objective of the present invention to provide a photo sensor having at least one switching element region and an electronic element region on a substrate. The photo sensor comprises a gate, a gate dielectric layer, a channel region, a source/drain, a diode stack, a photoelectrode, a insulating layer and a bias electrode. The gate is disposed on the switching element region of the substrate. The gate dielectric layer covers the gate and the substrate. The channel region is disposed on the gate dielectric layer above the gate. The source/drain is disposed on the opposite sides of the channel region and covers the gate dielectric layer underneath the opposite sides of the channel region. The diode stack is disposed on at least one of the source/drain in the electronic element region. The photoelectrode is disposed on the diode stack. The insulating layer covers the source/drain, the channel region, the diode stack and the photoelectrode, and has a opening to expose a part of the photoelectrode on the diode stack. The bias electrode is disposed on a part of the insulating layer on the source/drain and connects to one side of the photoelectrode near the source/drain along the opening.

In the foregoing, a diode of a photo sensor can be fabricated by the manufacturing process described herein with only one photolithography performed. According to the method above, a source/drain is directly formed on a gate dielectric layer so that the conventional plug structure can be omitted. Meanwhile, since a diode is formed on the source/drain, the structure of the photo sensor can be simplified. As a result, the times of the photolithography performed can be reduced to 6-7 times and also the number of the masks used. This improved fabricating process brings the cost down.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a cross section view of a photo sensor according to one embodiment of the present invention;

FIGS. 2A-2J illustrate cross section views of the photo sensor of FIG. 1 at each manufacturing stage; and

FIG. 3 illustrates a cross section view of the photo sensor having a protective layer according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

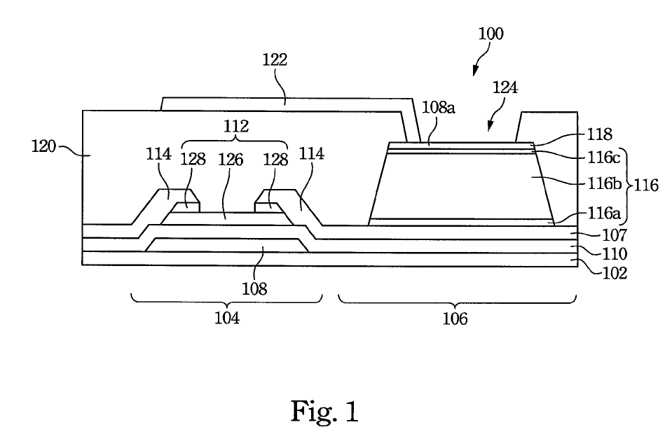

Refer to FIG. 1, it illustrates a cross section view of a photo sensor according to one embodiment of the present invention. As show in FIG. 1, the photo sensor 100 is arranged on a substrate 102 which can be divided into a switching element region 102 and an electronic element region 104. The photo sensor 100 comprises a gate 108, a gate dielectric layer 110, a channel region 112, a source/drain 114, a diode stack 116, a photo electrode 118, a insulating layer 120 and a bias electrode 122. The gate 108 is disposed on the switching element region 104 of the substrate 102 and the gate dielectric layer 110 covers the gate 108 and the substrate 102. The channel region 112 is disposed on the gate dielectric layer 110 above the gate 108, and comprises a semiconductor layer 126 and an electrical property enhancement layer 128 disposed on both sides of the semiconductor layer 126. The source/drain 114 is disposed on the electrical property enhancement layer 128 of the channel region 112 and covers the gate dielectric layer 110 underneath the channel region 112.

A diode stack 116 is arranged on one of the source/drain 114 in the electronic element region 106 of the substrate 102 and the photoelectrode 118 is disposed on the diode stack 116. The insulating layer 120 covers the source/drain 114, the channel region 112, the diode stack 116 and both sides of the photoelectrode 118, and has a opening 124 to expose a part of the photoelectrode 118 on the diode stack 116. The bias electrode 122 is disposed on a part of the insulating layer 120 on the source/drain 114 and connects to one side 118a of the photoelectrode 118 near the source/drain 114 along the opening 124.

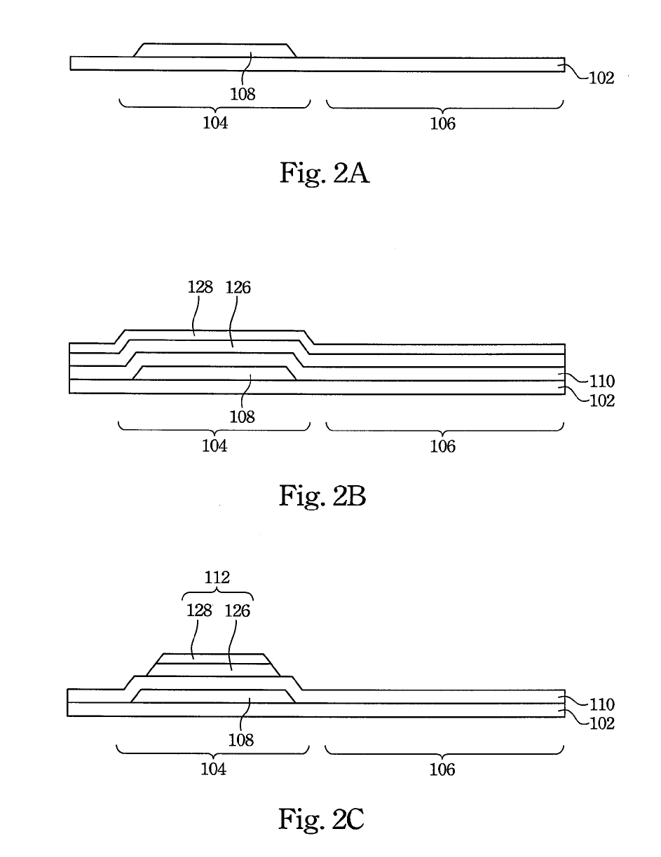

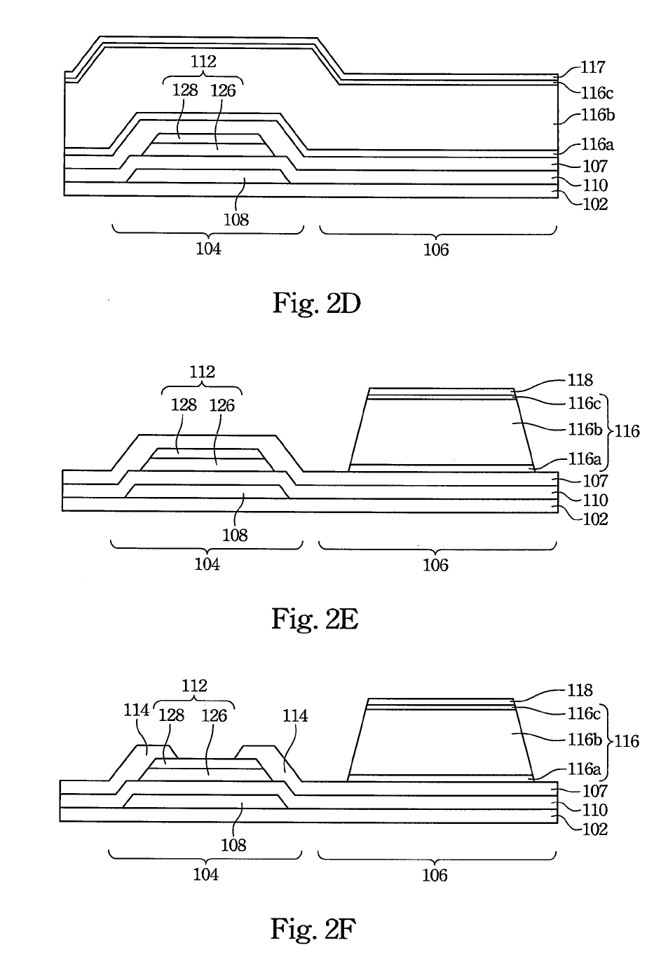

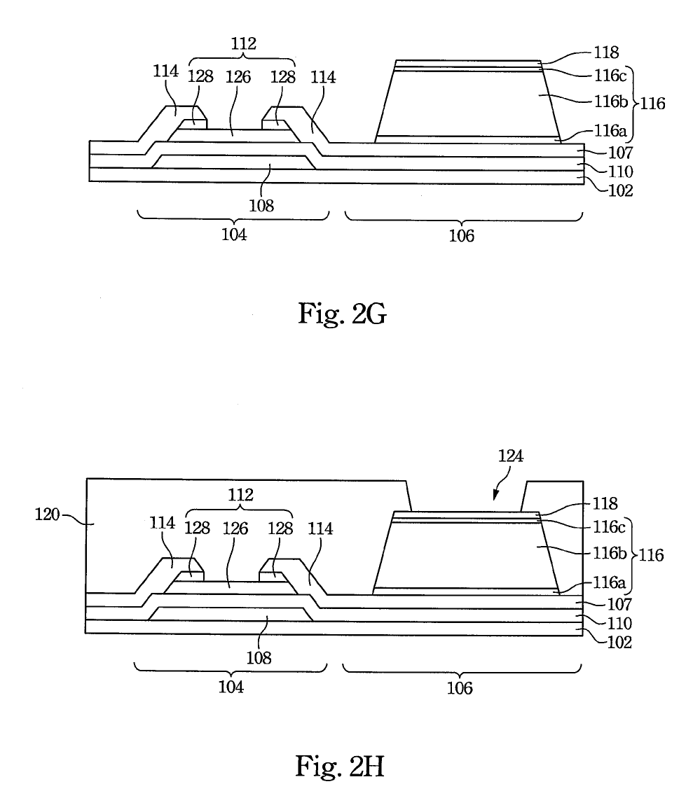

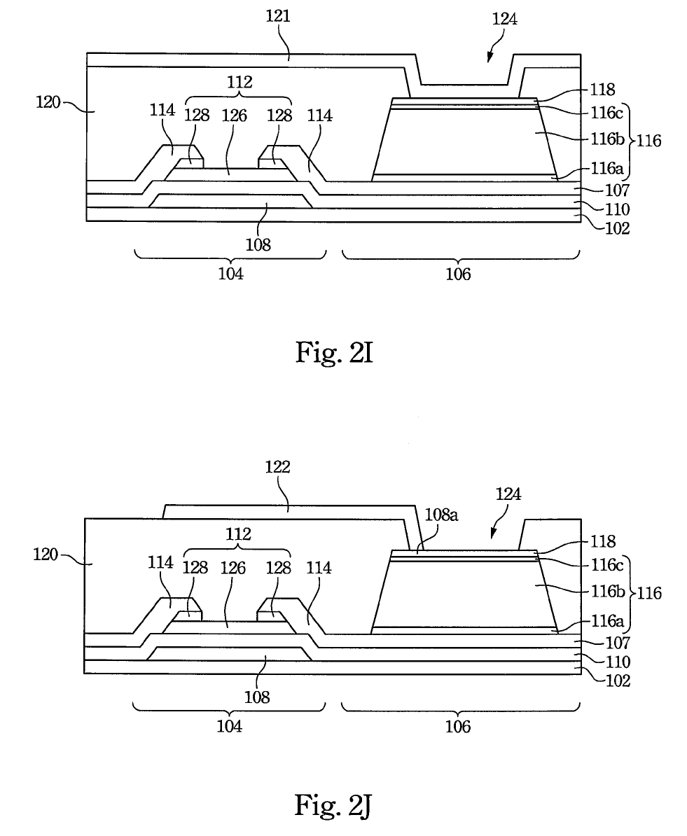

Next, FIGS. 2A-2J illustrate cross section views of the photo sensor 100 of FIG. 1 described above at each manufacturing stage. As shown in FIG. 2A, a substrate 102 is provided first, wherein the substrate 102 has a switching element region 104 and an electronic element region 106. Next, a gate metal layer (not shown) is formed on the substrate and then patterned to form a gate 108 on the switching element region 104 of the substrate 108. The substrate 102 is a transparent substrate, such as a glass substrate or a plastic substrate. The method used to form the gate metal layer can be physical vapor deposition, and the material used can be for example Mo, Cr, the alloy of Mo and Cr, the alloy of Mo and W, the complex material of Mo—Al—Mo or the complex material of Cr—Al—Cr. The thickness of the gate metal layer is around 2000-4000 Å.

Refer to FIG. 2B, a gate dielectric layer 110, a semiconductor layer 126, and an electrical property enhancement layer 128 are formed in sequence on the gate 108 and the substrate 102. The method used to form these three layers can be chemical vapor deposition wherein the thickness of the gate dielectric layer is around 2500-4000 Å and is made of silicon nitride. The thickness of the semiconductor layer 126 is around 4000-1500 Å and the material thereof is amorphous silicon. The thickness of the electrical property enhancement layer 128 is around 1000-100 Å and the material is doped silicon.

Refer to FIG. 2C, the electrical property enhancement layer 128 and the semiconductor layer 126 are patterned to form a channel region 112 on the gate dielectric layer 110 above the gate 108.

After that, Refer to FIG. 2D, a first conductive layer 107, a plurality of element function layers 116a, 116b, 116c and a second conductive layer 117 are formed in sequence on the gate dielectric layer 110 and the channel region 112. The element function layers 116a, 116b and 116c are a first doping layer, an intrinsic semiconductor layer, and a second doping layer, respectively. In the embodiment, the method used to form the element function layers 116a, 116b and 116c can be chemical vapor deposition. The element function layer 116a is an n-doped silicon layer with thickness 250-500 Å. The element function layer 116b layer is an amourphous silicon layer with thickness 4500-8000 Å. The element function layer 116c layer is a p-doped silicon layer with thickness 110-200 Å. However, in the embodiment, the element function layers 116a and 116c are used as exemplified, which can also be p-doped silicon layer and n-doped silicon layer, respectively. The first conductive layer 107 and the second conductive layer 117 can be formed by physical vapor deposition wherein the first conductive layer 107 can be metal, such as copper or the alloy thereof, with thickness 2000-4000 Å. The second conductive layer 117 is made of a transparent material, such as indium tin oxide, aluminum zinc oxide, indium zinc oxide, cadmium zinc oxide or the combination thereof, with thickness 300-500 Å. In the following process described, the first conductive layer 107 and the element function layer 116a-116c will further form a source/drain and a diode stack, respectively.

Refer to FIG. 2E, the second conductive layer 117 and the element function layers 116a-116c are patterned so that the element function layers 116a-116c turns into a diode stack 116 on the first conductive layer 107 of the electronic element region 106, and the second conductive layer 117 becomes a photoelectrode 118 on the diode stack 116. Since the photo electrode 118 is made of transparent material, light can directly pass through the photo electrode 118 and then to the diode stack 116 to generate a current, while using the photo sensor 110.

Refer to FIG. 2F, the first conductive layer 107 is patterned to form a source/drain 114 above the opposite sides of the channel region 112 and expose a part of the electrical property enhancement layer 128. The electrical property enhancement layer 128 in the channel region 112 is used to reduce the resistance between the semiconductor layer 126 and the source/drain and 114 to enhance Ohmic Contact property. Ohmic Contact property is that the contact resistance between two different materials is small and steady, which will not change as the voltage is changed. Since there is a difference between the energy level of the amorphous silicon material used for the semiconductor layer 126 and that of the metal used for the source/drain 114, this results in increasing the resistivity. Therefore, by arranging a high doped electrical property enhancement layer 128 between the semiconductor layer 126 and the source/drain 114, electrons can flow between the metal and the semiconductor material much more easily so that the Ohmic Contact property can be improved. Similarly, in the embodiment of the present invention, the Ohmic Contact property between the element function layer 116b and the first conductive layer 107, and between the element function layer 116b and the photoelectrode 118 can be improved by the element function layers 116a (an n-doped silicon layer) and the element function layers 116c (a p-doped silicon layer), respectively.

Refer to FIG. 2G, after patterning the first conductive layer 107 is completed, the electrical property enhancement layer 128 is selectively etched to expose a part of the semiconductor layer 126.

Next, refer to FIG. 2H, a insulating layer 120 is formed to cover the source/drain 114, the channel region 112, the diode stack 116 and the photoelectrode 118. After that, the insulating layer 120 is patterned to form an opening 124 in the insulating layer 120 so that a part of the photoelectrode 118 is exposed. In the embodiment, the thickness of the insulating layer 120 is 0.5-1.6 μm and can be made of silicon nitride, silicon oxynitride, or photoresist, such as phenolic resin, or black matrix photoresist (e.g. the photoresist comprises epoxy resin (Novolac), or acrylic resin).

Refer to FIG. 2I, the third conductive layer 121 is formed on the second conductive layer 117 in the opening 124 and the insulating layer 120. The thickness of the third conductive layer 121 is 2000-4000 Å and the material used of it is metal, such as copper.

Refer to FIG. 2J, the third conductive layer 121 is patterned so that the third conductive layer 121 patterned forms a bias electrode 122. As shown in FIG. 2J, the bias electrode 122 covers a part of the insulating layer 120 above the source/drain 114 and connects to one side 118a of the photoelectrode 118 near the source/drain 114 along the opening 124. The bias electrode 122 not only provides a bias voltage for the diode stack 126, but also is an effective shield against the light.

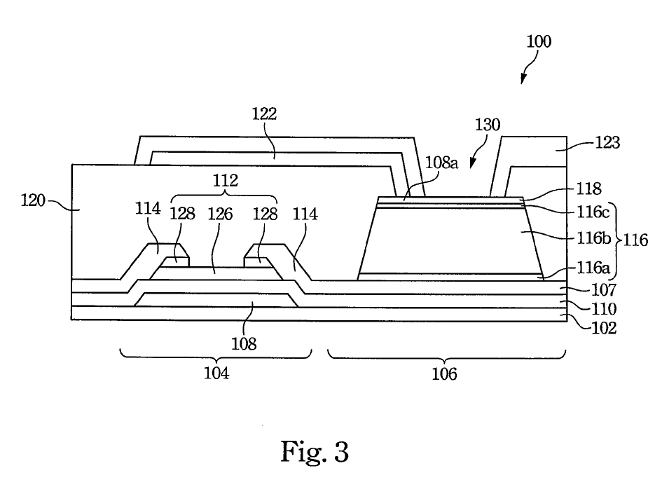

Furthermore, refer to FIG. 3, it illustrates a cross section view of the photo sensor 100 according to another embodiment of the present invention. In the embodiment, to provide sufficient protection for the photo sensor 100, a protective layer 123 is formed to cover the insulating layer 120, the bias electrode 122 and the photoelectrode 118. Then, the protective layer 123 is patterned so that the protective layer 123 patterned covers the bias electrode 122 and the insulating layer 120 in the electronic element region 106, and a lighting opening 130 is formed above the diode stack 116 to expose a part of the photoelectrode 118. In the embodiment, the material used for the protective layer 123 depends on the insulating layer 120. For example, while the material used for the insulating layer 120 is silicon nitride, or silicon oxynitride, the protective layer 123 can be made of silicon nitride, silicon oxynitride, common photoresist or resin type black matrix photoresist. While the material of the insulating layer 120 is common photoresit or resin type black matrix photoresist, the material used for the protective layer 123 should be the same as that of the insulating layer 120.

According to the manufacturing process described above, the diode structure can be formed by performing only one time photolithography. In addition to that, the source/drain manufactured by this method does not have to use the conventional plug structure. Meanwhile, the diode stack is arranged on one of the source/drain so that the structure of the photo sensor is simplified. Compared with the conventional process, the times of photolithography performed can be reduced to 6-7 times (as shown in FIGS. 1, 2C, 2E, 2F, 2H, 2J and 3) which simplify the manufacturing process and the numbers of the mask used. Hence, the cost and time are decreased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing photo sensor, comprising:
providing a substrate having a switching element region and an electronic element region;
forming a gate on the switching element region of the substrate;
forming a gate dielectric layer, a semiconductor layer, and an electrical property enhancement layer in sequence to cover the gate and the substrate;
patterning the electrical property enhancement layer and the semiconductor layer to form a channel region on the gate dielectric layer above the gate;
forming a first conductive layer, a plurality of element function layers and a second conductive layer in sequence to cover the gate dielectric layer and the channel region;
patterning the second conductive layer and the element function layers wherein the element function layers patterned form a diode stack on the first conductive layer of the electronic element region, and the second conductive layer patterned forms a photoelectrode on the diode stack;
patterning the first conductive layer to form a source/drain above the opposite sides of the channel region and expose a part of the electrical property enhancement layer;
forming a insulating layer to cover the source/drain, the diode stack and the photoelectrode;
patterning the insulating layer to form an opening in the insulating layer and the opening exposes the photoelectrode;
forming a third conductive layer to cover the insulating layer and the photoelectrode; and
patterning the third conductive layer so that the third conductive layer patterned covers a part of the insulating layer above the source/drain and connects to one side of the photoelectrode near the source/drain along the opening.

2. The method of claim 1, further comprising forming a protective layer to cover the insulating layer, the third conductive layer and the photoelectrode after patterning the third conductive layer.

3. The method of claim 2, further comprising patterning the protective layer so that the protective layer patterned covers the third conductive layer and a lighting opening is formed above the diode stack to expose a part of the photoelectrode.

4. The method of claim 1, wherein the element function layers comprise a first doping layer, an intrinsic semiconductor layer, and a second doping layer.

5. The method of claim 4, wherein the first doping layer is an n-doped silicon layer and the second doping layer is a p-doped silicon layer.

6. The method of claim 4, wherein the intrinsic semiconductor layer is an amorphous silicon layer.

7. The method of claim 1, wherein the electrical property enhancement layer is an n-doped silicon layer.

8. The method of claim 1, further comprising etching the electrical property enhancement layer to expose a part of the semiconductor layer after patterning the first conductive layer and prior to forming the insulating layer.

9. The method of claim 1, wherein the thickness of the insulating layer is at least 0.5 μm.

10. The method of claim 1, wherein the thickness of the insulating layer is 0.5-1.6 μm.

11. The method of claim 1, wherein the material of the insulating layer is silicon nitride, silicon oxynitride, or photoresist.

12. The method of claim 11, wherein the photoresist is resin type black matrix photoresist.

13. The method of claim 11, wherein the photoresist is phenolic resin, epoxy resin, or acrylic resin.

14. A photo sensor having at least one switching element region and an electronic element region on a substrate, wherein the photo sensor comprises:
a gate disposed on the switching element region of the substrate;
a gate dielectric layer covering the gate and the substrate;
a channel region disposed on the gate dielectric layer above the gate;
a source/drain disposed on the opposite sides of the channel region and covering the gate dielectric layer underneath the opposite sides of the channel region;
a diode stack disposed on at least one of the source/drain in the electronic element region;
a photoelectrode disposed on the diode stack;
a insulating layer covering the source/drain, the channel region, the diode stack and the photoelectrode, and having a opening to expose a part of the photoelectrode on the diode stack; and
a bias electrode disposed on a part of the insulating layer on the source/drain and connecting to one side of the photoelectrode near the source/drain along the opening.

15. The photo sensor of claim 14, further comprising a protective layer disposed on the bias electrode and the insulating layer of the electronic element region, and having a lighting opening to expose a part of the photoelectrode.

16. The photo sensor of claim 14, wherein the channel region comprises:
a semiconductor layer; and
an electrical property enhancement layer disposed on both sides of the semiconductor layer.

17. The photo sensor of claim 14, wherein the electrical property enhancement layer is an n-doped silicon layer.

18. The photo sensor of claim 14, wherein the diode stack comprises a first doping layer, an intrinsic semiconductor layer, and a second doping layer.

19. The photo sensor of claim 18, wherein the first doping layer is an n-doped silicon layer and the second doping layer is a p-doped silicon layer.

20. The photo sensor of claim 18, wherein the intrinsic semiconductor layer is an amorphous silicon layer.

21. The photo sensor of claim 14, wherein the thickness of the insulating layer is at least 0.5 μm.

22. The photo sensor of claim 14, wherein the thickness of the insulating layer is 0.5-1.6 μm.

23. The photo sensor of claim 14, wherein the material of the insulating layer is silicon nitride, silicon oxynitride, or photoresist.

24. The photo sensor of claim 23, wherein the photoresist is resin type black matrix photoresist.

25. The photo sensor of claim 23, wherein the photoresist is phenolic resin, epoxy resin, or acrylic resin.
